(19) United States
(12) Patent Application Publication
(10) Pub. No.: US 2012/0037941 A1
(43) Pub. Date: Feb. 16, 2012

(54) Red Emitting Luminescent Materials

(75) Inventors: Peter Josef Schmidt, Aachen (DE); Martin Zeuner, Munchen (DE); Wolfgang Schnick, Gauting (DE); Sandro Pagano, Germering (DE)

(73) Assignee: KONINKLIJKE PHILIPS ELECTRONICS N.V., Eindhoven (NL)

(21) Appl. No.: 13/264,174

(22) PCT Filed: Apr. 8, 2010
(86) PCT No.: PCT/IB2010/051515

§ 371 Date: Oct. 13, 2011

(30) Foreign Application Priority Data
Apr. 16, 2009 (EP) 09158002.7

(51) Int. Cl. H01L 33/50; C09K 11/79

(52) U.S. Cl. 257/98; 252/301.4 R; 257/E33.061

(57) ABSTRACT

The invention relates to an improved red light emitting material of the formula ML_{i2-y}Mg_{y}Si_{2-x-y}A_{x+y}N₄₋ₓOₓ:RE. (M=alkaline earth element, A=Al, Ga, B). This material crystallizes in a cubic structure type, making it useful for many applications.

### FIELD OF THE INVENTION

The present invention is directed to novel luminescent materials for light emitting devices, especially to the field of novel luminescent materials for LEDs

### BACKGROUND OF THE INVENTION

Phosphors comprising silicates, phosphates (for example, apatite) and aluminates as host materials, with transition metals or rare earth metals added as activating materials to the host materials, are widely known. As blue LEDs, in particular, have become practical in recent years, the development of white light sources utilizing such blue LEDs in combination with such phosphor materials is being energetically pursued.

Especially red emitting luminescent materials have been in the focus of interest and several materials have been proposed, e.g. U.S. Pat. No. 6,680,569(B2), “Red Deficiency Compensating Phosphor for a Light Emitting Device”, or from WO patent application 2005/052087 A1.

However, there is still the continuing need for red or orange-red emitting luminescent materials which are usable within a wide range of applications and especially allow the fabrication of warm white phosphor coated light emitting diodes(pcLEDs) with optimized luminous efficiency and color rendering.

### SUMMARY OF THE INVENTION

It is an object of the present invention to provide a material which is usable within a wide range of applications and especially allows the fabrication of phosphor warm white pcLEDs with optimized luminous efficiency and color rendering.

This object is solved by a material according to claim 1 of the present invention. Accordingly, a material MLi_{2-y}Mg_{y}Si_{2-x-y}A_{x+y}N₄₋ₓOₓ:RE is provided, whereby

A is selected out of the group comprising Al, Ga, B, or mixtures thereof;

M is selected out of the group comprising Ca, Sr, and Ba, or mixtures thereof;

RE is selected out of the group comprising rare earth metals, Y, La, Sc, or mixtures thereof;

and x is ≧0 and ≦2, y is ≧0 and ≦2, and x+y≦2.

It should be noted that by the term “MLi_{2-y}Mg_{y}Si_{2-x-y}A_{x+y}N₄₋ₓOₓ:RE” especially and/or additionally any material is meant and/or included, which has essentially this composition.

The term “essentially” means especially that ≧95%, preferably ≧97% and most preferred ≧99% wt-%. However, in some applications, trace amounts of additives may also be present in the bulk compositions. These additives particularly include such species known to the art as fluxes. Suitable fluxes include alkaline earth—or alkaline—metal oxides, borates, phosphates and halides such as fluorides, ammonium chloride, SiO₂ and the like and mixtures thereof.

Such a material has shown for a wide range of applications within the present invention to have at least one of the following advantages:

Using the material as luminescent material, LEDs may be built which show improved lighting features, especially thermal stability.

The Material may be made at lower temperatures than many other similar materials known in the field (e.g. M₂Si₅N₈-materials) and can be produced using bulk-techniques.

The Material shows for a wide range of applications a cubic crystal lattice, which is advantageous for many applications as will be explained in more detail later on. The Material for a wide range of applications only contains non-toxic and widely available constituents.

Without being bound to any theory, the inventors believe that the improved properties of the inventive material arise at least partially out of the structure of the material.

It is believed that the inventive material essentially has a cubic structure. The host lattice structure consist of vertex sharing SiN₄ tetrahedra that form a 3 d network with the Li/Mg and Ca/Sr atoms located in the structural voids. The RE-dopant is located on Sr/Ca positions, whereas both crystallographically independent Sr/Ca sites are trigonal prismatic coordinated by nitrogen ligands. Similar structural motifs are known for AB₂X₄ compounds of composition CaB₂O₄, SrB₂O₄, BaAl₂S₄, and BaGa₂S₄ (Net 39, see M. O'Keeffe, Acta. Cryst. A48 (1992) 670).

Study of certain compounds within the inventive material has found that they are crystallizing in a cubic crystal structure (space group Pa-3) with lattice constants ranging from a₀=10.713(1) Å for SrLi₂Si₂N₄:Eu to a₀=10.568(1) Å for CaLi₂Si₂N₄:Eu.

Surprisingly as a result, the spectrum may be tuned by adjusting the Sr/Ca ratio in the lattice. It was found that increasing the Sr/Ca ratio does not lead to a blue shift of emission as, usually found for other Eu(II) phosphors such as (Sr,Ca)S:Eu, but to a red shift. The most red shifted color point is thus obtained for a pure Sr containing compound. A further red shift of emission is in some applications of the invention possible by incorporating Ba in the lattice.

According to a preferred embodiment of the present invention, RE is selected out of the group comprising Ce, Eu, or mixtures thereof.

According to a preferred embodiment of the present invention, the doping level of RE is ≧0.02% and ≦10%. This has been shown to lead to a material with further improved lighting features for a wide range of application within the present invention. Preferably, the doping level is ≧0.2% and ≦3%, more preferred ≧0.75% and ≦2%.

According to a preferred embodiment of the present invention, x is ≧0.1 and ≦1.5; preferably ≧0.5 and ≦1.5. This has been found advantageous for some applications within the present invention due to the usually observed slight blue-shift of the spectrum of the material.

According to a preferred embodiment of the present invention, y is ≧0.1 and ≦1.5; preferably ≧0.5 and ≦1.5. The substitution of Li against Mg has been found advantageous for many applications within the present invention due to the enhanced stability of many of the resulting compounds.

The present invention furthermore relates to the use of the inventive material as a luminescent material.

The present invention furthermore relates to a light emitting device, especially a LED, comprising at least one material as described above.

According to a preferred embodiment of the present invention the inventive material is made by mixing suitable precursor or “source”-materials, firing up to a temperature between·800° C. and·1200° C. and cooling, preferably with·5K/h and·150K/h.

Suitable precursor and/or source materials may be:

Element Preferred Precursor and/or Source material

Ca, Sr, Ba The material as metal, amide, nitride, azide, silicide, alloy or as hydride

Li, Mg Metal, hydride, amide, nitride, alloy, silicide, azide

Si Si(NH)₂, metallic silicon, silicon carbodiimide, Si(CN₂)₂, silicide, silicon nitride

Al Al₂O₃, AN, halide, metallic aluminum, LiA1H₄

RE Metal, hydride, oxide, amide, azide, halogenide (especially fluoride)

N as amide, azide or nitride; may also be introduced via nitridation (see below)

O oxide, carbonate

According to a further and/or alternative embodiment, the inventive material may be made by first providing a suitable Zintl type phase of mixed metals (e.g. (Sr,Ca)Li₂Si₂:Eu or other suitable Zintl type phase mixtures), which is then nitridated by a self propagating high temperature nitridation reaction under an elevated nitrogen pressure (e.g. 100 bar). In case oxygen is present in the desired material, it can e.g. be introduced by admixing a suitable oxide or carbonate. This preparation method has the advantage that it may be used for bulk preparation.

Large volume bulk preparation can for most applications be achieved by heating under a stagnant atmosphere of dry nitrogen in tungsten or molybdenum crucibles.

Preferably the at least one material is provided as powder and/or as ceramic material.

If the at least one material is provided at least partially as a powder, it is especially preferred that the powder has a d₅₀ of·5·m and·20·m, preferably·10·m and ·15·m. This has been shown to be advantageous for a wide range of applications within the present invention.

According to a preferred embodiment of the present invention, the at least one material is at least partly provided as at least one ceramic material.

The term “ceramic material” in the sense of the present invention means and/or includes especially a crystalline or polycrystalline compact material or composite material with a controlled amount of pores or which is pore free (i.e. 100% theoretical density. . .

The term “polycrystalline material” in the sense of the present invention means and/or includes especially a material with a volume density larger than 90 percent of the main constituent, consisting of more than 80 percent of single crystal domains, with each domain being larger than 0.5 μm in diameter and having different crystallographic orientations. The single crystal domains may be connected by amorphous or glassy material or by additional crystalline constituents.

The providement of the inventive material as a ceramic is especially preferred due to the cubic structure of the material, making the ceramic body optically isotropic and thus high optical transparency can be achieved, in contrast to prior art red phosphor materials.

According to a preferred embodiment, the at least one ceramic material has a density of ≧90% and ≦100% of the theoretical density. This has been shown to be advantageous for a wide range of applications within the present invention since then the luminescence and optical properties of the at least one ceramic material may be increased.

More preferably the at least one ceramic material has a density of ≧97% and ≦100% of the theoretical density, yet more preferred ≧98% and ≦100%, even more preferred ≧98.5% and ≦100% and most preferred ≧99.0% and ≦100%.

According to a preferred embodiment of the present invention, the surface roughness RMS (disruption of the planarity of a surface; measured as the geometric mean of the difference between highest and deepest surface features) of the surface(s) of the at least one ceramic material is ≧0.001 μm and ≦5 μm.

According to an embodiment of the present invention, the surface roughness of the surface(s) of the at least one ceramic material is ≧0.005 μm and ≦0.8 μm, according to an embodiment of the present invention ≧0.01 μm and ≦0.5 μm, according to an embodiment of the present invention ≧0.02 μm and ≦0.2 μm. and according to an embodiment of the present invention ≧0.03 μm and ≦0.15 μm.

According to a preferred embodiment of the present invention, the specific surface area of the at least one ceramic material is ≧10⁻⁷ m²/g and ≦0.1 m²/g.

A material and/or a light emitting device (such as an LED) comprising a material according to the present invention may be of use in a broad variety of systems and/or applications, amongst them one or more of the following:
Office lighting systems,
household application systems,
shop lighting systems,
home lighting systems,
accent lighting systems,
spot lighting systems,
theater lighting systems,
fiber-optics application systems,
projection systems,
self-lit display systems,
pixelated display systems,
segmented display systems,
warning sign systems,
medical lighting application systems,
indicator sign systems,
decorative lighting systems,
portable systems,
automotive applications, and
green house lighting systems.

The aforementioned components, as well as the claimed components and the components to be used in accordance with the invention in the described embodiments, are not subject to any special exceptions with respect to their size, shape, material selection and technical concept, such that the selection criteria known in the pertinent field can be applied without limitations.

### BRIEF DESCRIPTION OF THE DRAWINGS

Additional details, features, characteristics and advantages of the object of the invention are disclosed in the subclaims, the figures and the following description of the respective figures and examples, which—in an exemplary fashion—show several embodiments and examples of a at least one ceramic material for use in a light emitting device according to the invention as well as several embodiments and examples of a light emitting device according to the invention.

FIG. 1 shows an X-ray diffraction spectrum of a material according to a first example of the present invention.

FIG. 2 shows emission and excitation spectra of the material of FIG. 1.

FIG. 3 shows a micrograph of the material of FIG. 1.

FIG. 4 shows an emission spectrum of a material according to a second example of the present invention.

FIG. 5 shows an emission spectrum of a material according to a fifth example of the present invention.

The invention will be further understood by the following Examples I to V which—in a merely illustrative fashion—shows several materials of the present invention.

### EXAMPLE I

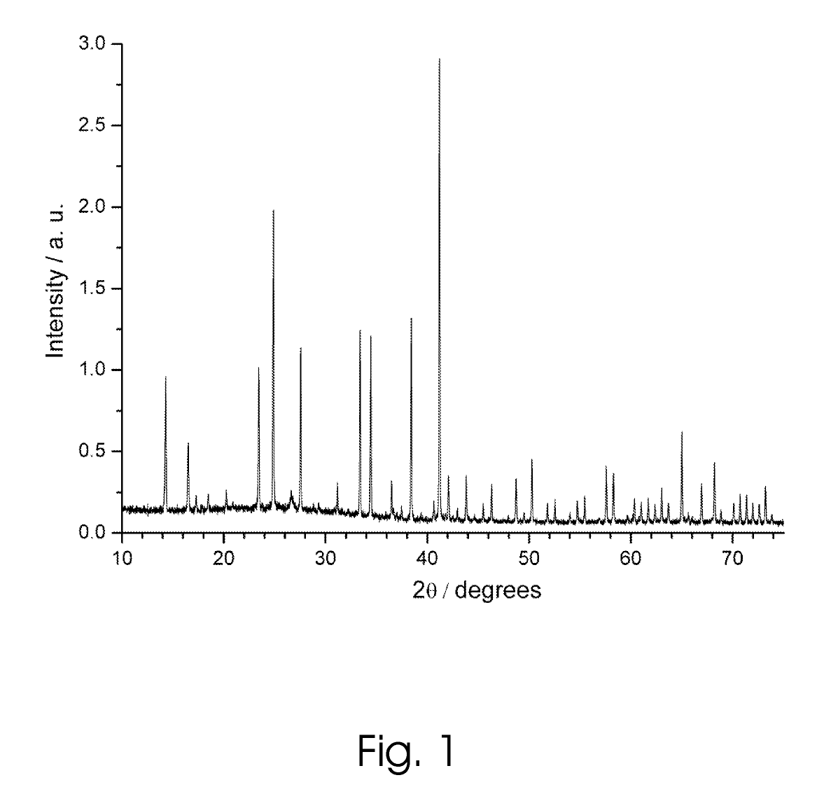

FIGS. 1, 2 and 3 refer to SrLi₂Si₂N₄:Eu(1%) which was made according to the following:

3 molar parts of Sr metal are mixed with 10 molar parts of Li metal, 2 molar parts of LiN₃, 3 molar parts of Si(NH)₂ and 0.03 molar parts of Eu(NH₂)₂. The mixture is heated with 2K/min in a closed tantalum crucible to 900° C. for 24 hrs in argon gas and is then cooled down with 5-11K/h.

The obtained SrLi₂Si₂N₄:Eu phosphor is then washed with water and ethanol to eliminate impurity phases and dried.

Alternatively the material can be made using a tungsten crucible. In this case the educts are heated in dry N₂ atmosphere in tungsten crucibles according to the following heating profile:

room temperature·12 h·900° C.·12 h·900° C.·24 h·700° C.·24 h·400C·45 min·RT

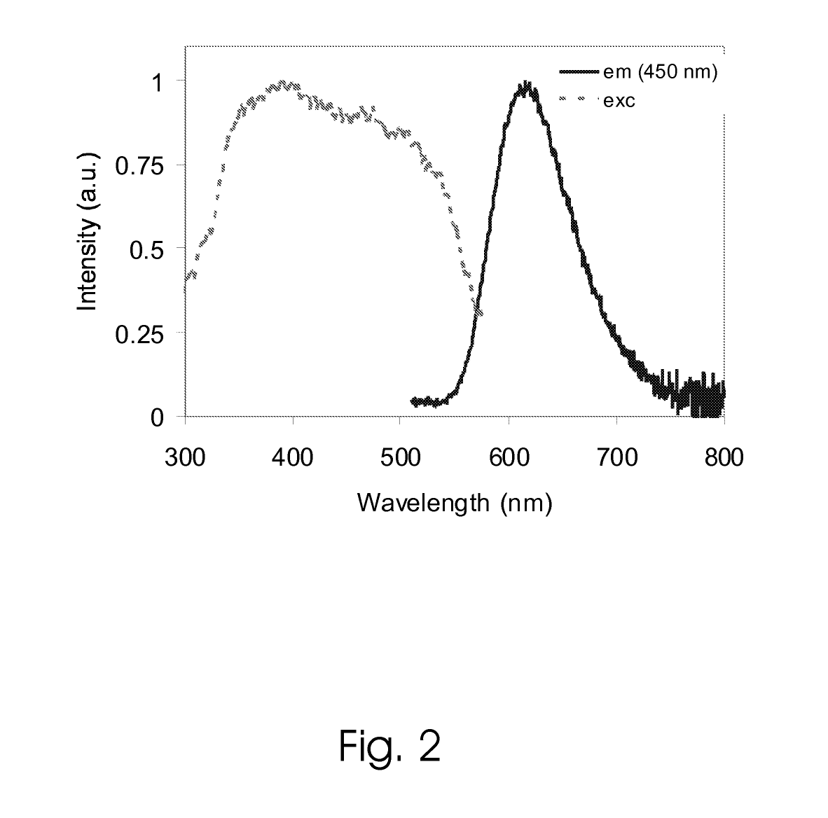

FIG. 1 shows the x-ray powder diffraction pattern of SrLi₂Si₂N₄:Eu, illustrating the cubic crystal structure of the material. FIG. 2 shows excitation (dotted) and emission (straight) spectra of a SrLi₂Si₂N₄:Eu(1%) powder sample. As can be seen from the excitation spectrum the material can be efficiently excited in the 350-530 nm spectral range and is thus well suited for application in phosphor converted LEDs. The emission maximum peaks at 615 nm. The Stokes shift of ˜2580 cm⁻¹ is rather small and leads to good thermal stability of the emission properties.

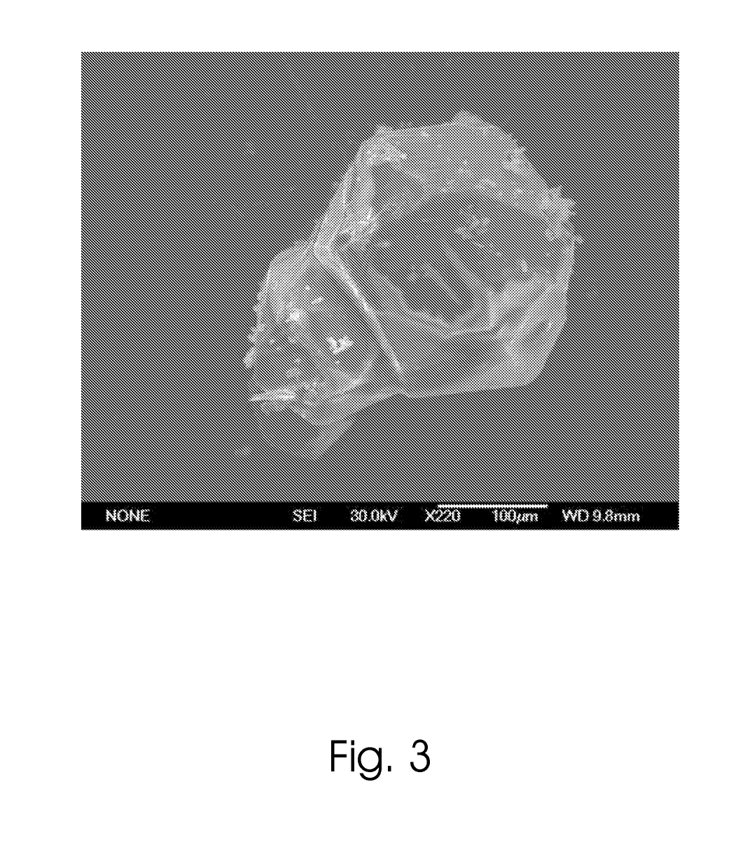

FIG. 3 shows a SEM micrograph of a crystallite of the powder sample. The icosahedral shape reflects the cubic crystal lattice symmetry. Table 1 summarizes the emission properties of SrLi₂Si₂N₄:Eu(1%):

TABLE I

| | exc | abs | CIE | CIE | LE |
|---|---|---|---|---|---|
| Sample | (nm) | (%) | x | y | (lm/W) |
| SrLi₂Si₂N₄: Eu | 450 | 81.9 | 0.610 | 0.388 | 281.5 |

### EXAMPLE II

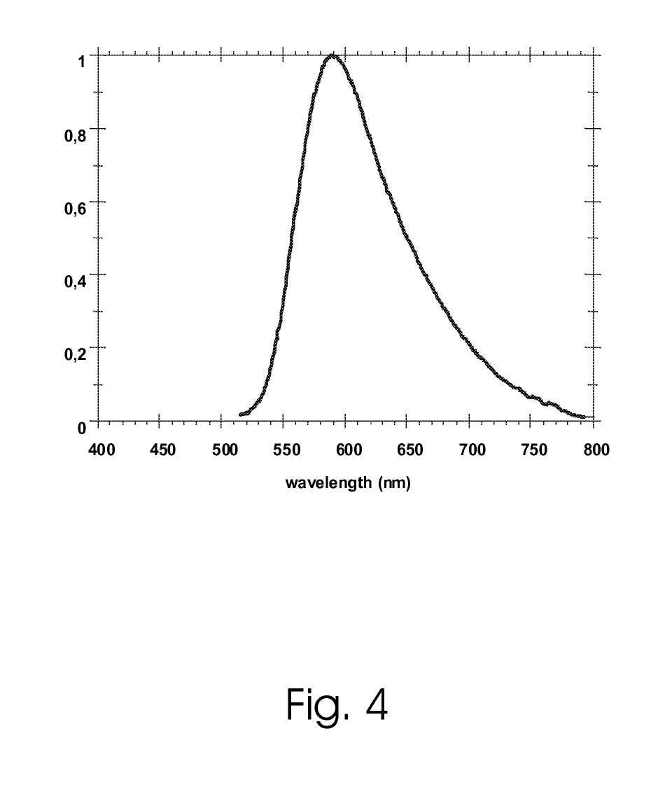

FIG. 4 refers to CaLi₂Si₂N₄:Eu which was made analogous to SrLi₂Si₂N₄:Eu(1%) by substituting Sr metal by Ca metal. The Fig. shows a blue-shifted emission spectrum compared to the Sr compound with an emission maximum at 590 nm.

### EXAMPLE III+IV

(Sr,Ca)Li₂Si₂N₄:Eu mixed crystals were prepared analogous to the Sr or Ca only containing compounds of Example I+II.

The resulting compounds Ca_{0.6}Sr_{0.4}Li₂Si₂N₄:Eu (Example III) and Ca_{0.25}Sr_{0.75}Li₂Si₂N₄:Eu (Example IV) show emission properties within the spectral range formed by the end members of the solid solution series, thus the emission properties can be tuned by changing the Sr/Ca ratio of the compounds. The following table shows emission properties of such mixed crystals.

TABLE II

| compound | CIE x | CIE y | λₘₐₓ (nm) | LE (lm/W) |
|---|---|---|---|---|
| Ca_{0.6}Sr_{0.4}Li₂Si₂N₄: Eu | 0.517 | 0.479 | 582 | 412 |
| Ca_{0.25}Sr_{0.75}Li₂Si₂N₄: Eu | 0.555 | 0.429 | 612 | 295 |

### EXAMPLE V

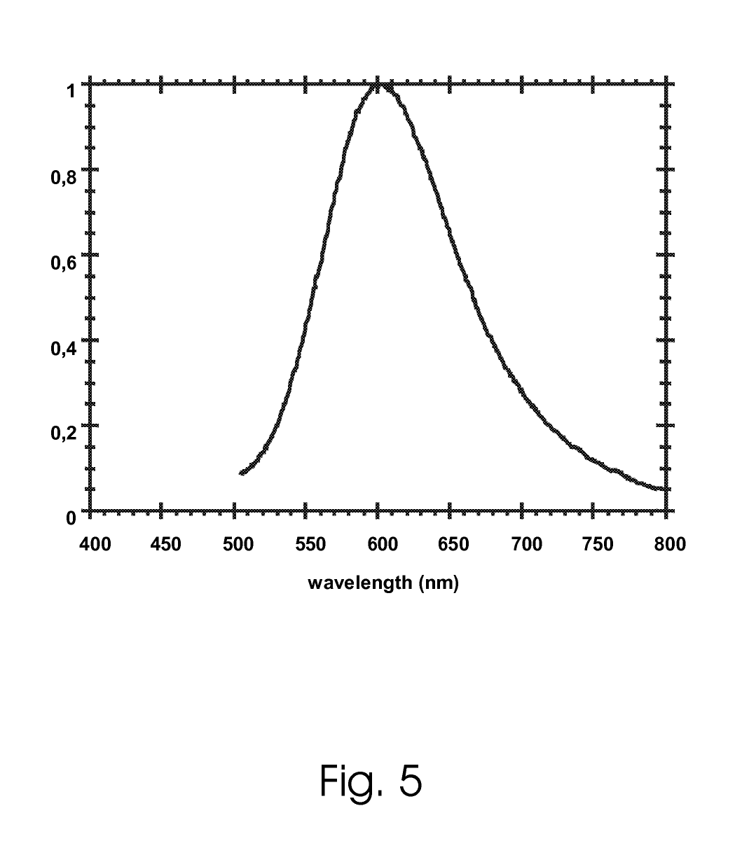

FIG. 5 refers to SrLi₂Si₂₋ₓAlₓN₄₋ₓOₓ:Eu (x=0.3) which was made analogous to SrLi₂Si₂N₄:Eu(1%) using AlCl₃ * x H₂O as Al and O source, respectively.

Compared to the pure nitridosilicate compound the SiAlON phase shows a slight blue shift and broadening of the emission band which may be explained by a statistical sustitution of Si and N sites by Al and O.

The particular combinations of elements and features in the above detailed embodiments are exemplary only; the interchanging and substitution of these teachings with other teachings in this and the patents/applications incorporated by reference are also expressly contemplated. As those skilled in the art will recognize, variations, modifications, and other implementations of what is described herein can occur to those of ordinary skill in the art without departing from the spirit and the scope of the invention as claimed. Accordingly, the foregoing description is by way of example only and is not intended as limiting. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage. The invention's scope is defined in the following claims and the equivalents thereto. Furthermore, reference signs used in the description and claims do not limit the scope of the invention as claimed.

Thus, in summary, the invention relates to an improved red light emitting material of the formula MLi_{2-y}Mg_{y}Si_{2-x-y}A_{x+y}N₄₋ₓOₓ:RE (M=alkaline earth element; A=Al, Ga, B; RE=rare earth metals, Y, La, Sc). This material crystallizes in a cubic structure type, making it useful for many applications.

1. A material comprising MLi_{2-y}Mg_{y}Si_{2-x-y}A_{x+y}N₄₋ₓOₓ:RE, wherein
A is selected out of the group comprising Al, Ga, B, or mixtures thereof,
M is selected out of the group comprising Ca, Sr, Ba, or mixtures thereof,
RE is selected out of the group comprising rare earth metals, Y, La, Sc, or mixtures thereof, and x is ≧0 and ≦2, y is ≧0 and ≦2 and x+y ≦2.

2. The material of claim 1, whereby RE is selected out of the group comprising Eu, Ce, or mixtures thereof.

3. The material of claim 1 or 2, whereby the doping level is ≧0.02% and ≦10%.

4. The material of any of the claims 1 to 3, whereby x is ≧0.1 and ≦1.5.

5. Use of a material according to claim 1 as a luminescent material.

6. Light emitting device comprising at least one material according to claim 1.

7. The light emitting device of claim 6, whereby the at least one material is provided as powder and/or as ceramic material.

8. The light emitting device of claim 7 whereby the powder has a d₅₀ of ≧5 μm and ≦20 μm.

9. The light emitting device of claim 7, whereby the ceramic has a density ≧90% of the theoretical density.

10. A system comprising a material according to claim 1 and/or a light emitting device according to claim 6, the system being used in one or more of the following applications:
Office lighting systems,
household application systems,
shop lighting systems,
home lighting systems,
accent lighting systems,
spot lighting systems,
theater lighting systems,
fiber-optics application systems,
projection systems,
self-lit display systems,
pixelated display systems,
segmented display systems,
warning sign systems,
medical lighting application systems,
indicator sign systems,
decorative lighting systems,
portable systems,
automotive applications, and
green house lighting systems.
